(19) United States
(12) Patent Application Publication
(10) Pub. No.: US 2016/0293597 A1
(43) Pub. Date: Oct. 6, 2016

(54) Integrated Semiconductor Device

(71) Applicant: Infineon Technologies Austria AG, Villach (AT)

(72) Inventors: Gilberto Curatola, Villach (AT); Frank Kahlmann, Neubiberg (DE)

(21) Appl. No.: 14/679,790

(22) Filed: Apr. 6, 2015

(51) Int. Cl. H01L 27/088; H01L 29/778

(52) U.S. Cl. CPC H01L 27/0883; H01L 29/778

(57) ABSTRACT

A semiconductor device includes a first semiconductor device, a second semiconductor device, and a third semiconductor device. The first semiconductor device and the second semiconductor device are integrated to form a half-bridge. The third semiconductor device is a normally-off semiconductor device that is arranged in series with the half-bridge.

### TECHNICAL FIELD

Embodiments of the present invention relate to an integrated semiconductor device, in particular comprising a half-bridge or a full bridge arrangement.

### BACKGROUND

U.S. Pat. No. 7,550,781 B2 discloses an integrated III-nitride power device with a co-packaging of at least two semiconductor devices in a common die, e.g., in half-bridge or full-bridge configurations. U.S. Pat. No. 6,649,287 B2 discloses GaN layered structures (buffer material) over a silicon substrate. U.S. Pat. No. 7,326,971 B2 discloses a normally-off GaN based HEMT (high-electron mobility device).

### SUMMARY

An embodiment relates to an integrated semiconductor device. This device includes a first semiconductor device, a second semiconductor device, and a third semiconductor device. The first semiconductor device and the second semiconductor device are integrated to form a half-bridge and the third semiconductor device is a normally-off semiconductor device that is arranged in series with the half-bridge.

### BRIEF DESCRIPTION OF THE DRAWINGS

Embodiments are shown and illustrated with reference to the drawings. The drawings serve to illustrate the basic principle, so that only aspects necessary for understanding the basic principle are illustrated. The drawings are not to scale. In the drawings the same reference characters denote like features.

FIG. 1 shows an exemplary integration of half-bridge configuration comprising two high-voltage wide bandgap transistors that are arranged in series with a normally off transistor;

FIG. 2 shows an exemplary monolithic approach of the III-V half-bridge semiconductor device according to FIG. 1;

FIG. 3 shows a full monolithical integrated GaN normally-off half-bridge arrangement;

FIG. 4 shows an alternative embodiment of a normally-off full-bridge (H bridge);

FIG. 5 shows another alternative embodiment based on FIG. 4, wherein an additional leg, i.e., a series connection of a high-side GaN MOSFETs is arranged in parallel to the first leg; and

FIG. 6 shows a further alternative embodiment based on FIG. 5, wherein at least one additional low-voltage normally-off transistor is placed in parallel to the low-voltage transistor.

### DETAILED DESCRIPTION OF ILLUSTRATIVE EMBODIMENTS

Examples described herein in particular refer to an integration of two or more wide bandgap transistors in a configuration to form an overall “normally-off” semiconductor arrangement, in particular chip or die, wherein such semiconductor arrangement may be packaged in a common package.

According to an exemplary embodiment a monolithic integration of III-V semiconductor devices in half-bridge configuration is provided.

Examples presented herein in particular refer to integrated solutions comprising at least two wide bandgap transistors such that they form a normally-off configuration. In particular, a full-bridge configuration or a half-bridge configuration comprising such transistors can be combined into one single package.

According to an exemplary embodiment, a fully monolithic solution is provided.

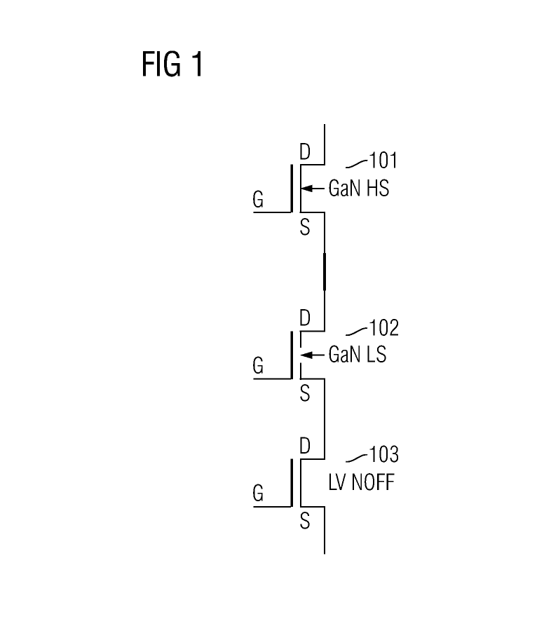

FIG. 1 shows an exemplary integration of half-bridge configuration comprising two high-voltage wide bandgap transistors 101 and 102, which can be normally-on transistors. Each transistor 101, 102 may be a high electron mobility transistor (HEMT) with a drain, a source and a gate. The transistor 101 may be a high-side (HS) GaN MOSFET and the transistor 102 may be a low-side (LS) GaN MOSFET. The drain of the transistor 101 is connected to a high voltage, the source of the transistor 101 is connected to the drain of the transistor 102. The source of the transistor 102 is connected in series across a low-voltage transistor 103. The transistor 103 is a normally-off transistor, which may in particular stop accidental short-through currents. The transistor 103 may be a low-voltage (LV) transistor; it may be a Si transistor or a wide bandgap device.

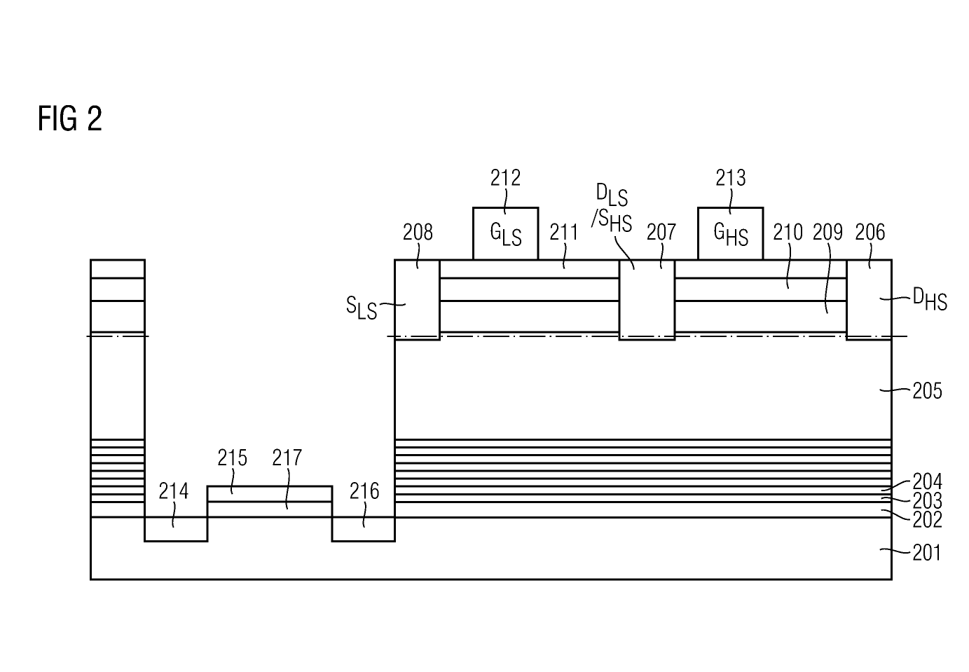

FIG. 2 shows an exemplary monolithic approach of the III-V half-bridge semiconductor device according to FIG. 1.

On top of a silicon substrate 201 is a layer 202 of AlN, on top of the layer 202, several layers 203 of GaN and several layers 204 of AlGaN are arranged (in alternating order).

On top of the last stacked layer of AlGaN a large layer of GaN 205 is provided. On top of the GaN layer 205 is a AlGaN barrier layer 209, on top of which another layer 210 of GaN is arranged. This layer may be referred to as GaN cap layer. However, the GaN cap layer 210 may be optional and it may in particular be omitted. On top of the layer 210 a passivation layer 211 is provided.

Metallic contacts (or electrodes) 206, 207 and 208 are arranged piercing through the layers 211, 210, 209 into the layer 205 (in fact reaching the electron gas between the layers 209 and 205).

On top of the passivation layer 211 a metallic contact (electrode) 212 is arranged between the contacts 208 and 207 and a metallic contact (electrode) 213 is arranged between the contacts 206 and 207.

The contact 208 corresponds to the source of the transistor 102, the contact 212 corresponds to the gate of the transistor 102, the contact 207 corresponds to the source of the transistor 101 and to the drain of the transistor 102, the contact 213 corresponds to the gate of the transistor 101 and the contact 206 corresponds to the drain of the transistor 101.

The low-voltage normally-off transistor 103 has its source 214 implanted in the silicon substrate 201 and its gate as a metallic contact 215 on top of a poly-silicon layer 217, which is arranged on top of the silicon substrate 201. The gate of the silicon transistor may be a metal electrode or a highly doped polysilicon layer. Between such metal contact and the silicon substrate a passivation layer, e.g., the gate oxide, may be interposed. The passivation layer may comprise SiO₂, a high-k dielectric material or the like. The drain 216 of the transistor 103 is implanted in the silicon substrate 201 and connected to the contact 208 of the source of the transistor 102. Hence, the transistor 103 is integrated in the silicon substrate 201 on top of which the GaN-based technology is grown.

After the GaN high-side and low-side transistors 101 and 102 are fabricated, a trench may be opened (e.g., via an etching step) in the GaN buffer that reaches down to the silicon substrate 201. This silicon substrate 201 may be <111> oriented, which may be different from a <100> orientation that may be conventionally used for Si-based technology. This may, however, suffice for the low-voltage normally-off transistor 103, because the transistor 103 may predominately act as a safety switch that blocks dangerous short circuit currents. A width of this transistor 103 may be chosen such that a parasitic series resistance introduced by transistor 103 is not of significance for the overall half-bridge performance.

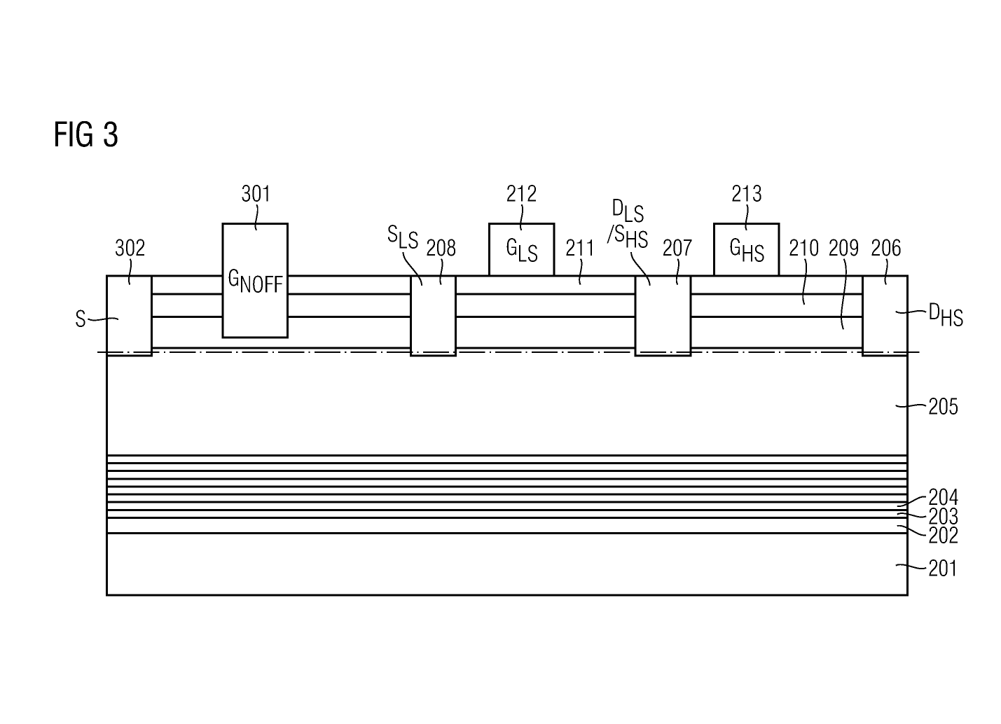

FIG. 3 shows a full monolithical integrated GaN normally-off half-bridge arrangement. In contrast to FIG. 2, the transistor 103 is also realized in GaN technology. This transistor 103 is of normally-off low-voltage type; there exist several options for realizing a normally-off GaN transistor, e.g., pGaN, recess and oxide, fluorine implantation, etc.

According to FIG. 3, the contact 208 is also the drain of the transistor 103. The gate of the transistor 103 corresponds to a (metallic) contact 301 that reaches into the barrier layer 209, but not to its underlying layer 205 of GaN. In case of a recess approach a gate isolation layer may be interposed between the metal electrode 301 and the AlGaN barrier layer 209. The gate isolation layer may comprise any gate oxide, e.g., SiN, a high-k dielectric, Al₂O₃. The source of the transistor 103 corresponds to a (metallic) contact 302 that reaches into the layer 205 (comparable to the contacts 206 to 208).

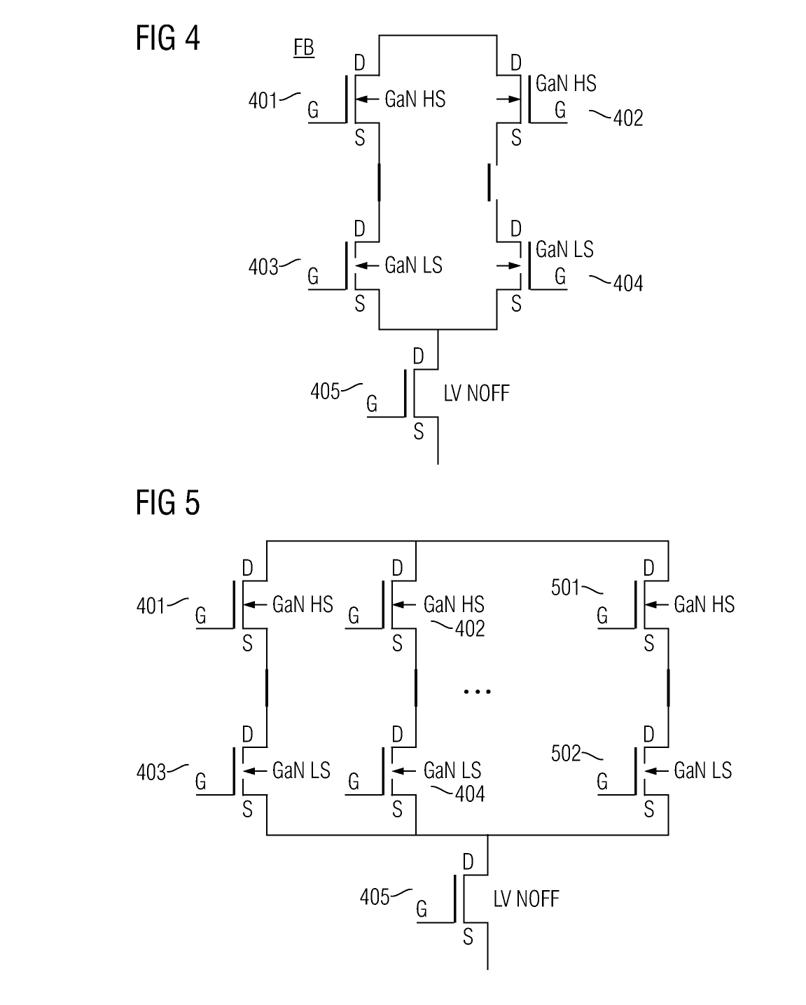

FIG. 4 shows an alternative embodiment of a normally-off full-bridge (H bridge) comprising two high-side GaN MOSFETs 401, 402 and two low-side GaN MOSFETs 403, 404, wherein the MOSFETs 401 and 403 are connected in series and the MOSFETs 402 and 404 are connected in series. Each series connection is also referred to as “leg”. Both series connections of MOSFETs (i.e. both legs) are arranged in parallel and this parallel arrangement of MOSFETs 401 to 404 is connected in series with a low-voltage normally-off transistor 405.

FIG. 5 shows another alternative embodiment based on FIG. 4, wherein an additional leg, i.e. a series connection of a high-side GaN MOSFET 501 and a low-side GaN MOSFET 502 is arranged in parallel to the first leg comprising the MOSFETs 401, 403 and the second leg comprising the MOSFET 402, 404. Hence, more than two legs (i.e. an “n-leg bridge implementation”) may be arranged in parallel and all those parallel connected legs are arranged in series with the low-voltage normally-off transistor 405.

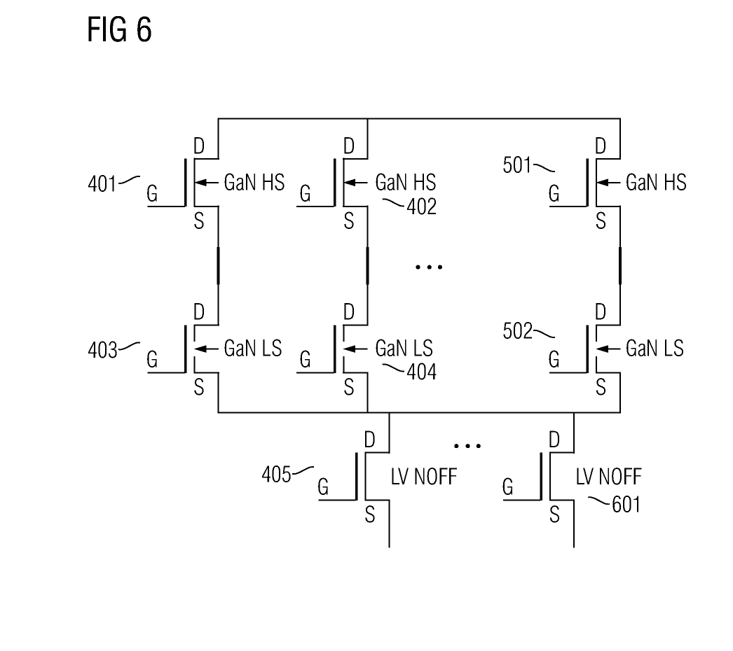

FIG. 6 shows a further alternative embodiment based on FIG. 5, wherein at least one additional low-voltage normally-off transistor 601 is placed in parallel to the transistor 405.

It is noted that the transistor 405 (and/or the transistor 601) may be a low-voltage silicon transistor or a wide bandgap low side transistor.

It is further noted that the GaN MOSFETs shown in the figures above, are exemplarily n-channel MOSFETs.

The examples suggested herein may in particular be based on at least one of the following solutions. In particular combinations of the following features could be utilized in order to reach a desired result. The features of the method could be combined with any feature(s) of the device, apparatus or system or vice versa.

An integrated semiconductor device is provided. The device comprises a first semiconductor device, a second semiconductor device, and a third semiconductor device, wherein the first semiconductor device and the second semiconductor device are integrated to form a half-bridge, and wherein the third semiconductor device is a normally-off semiconductor device that is arranged in series with the half-bridge.

Hence, due to the third semiconductor device (comprising at least one transistor, e.g., field effect transistor), an integrated solution of an overall normally-off arrangement is reached.

The half-bridge comprising the first and second semiconductor device (in series) may also be referred to as “leg.” Several such legs can be arranged in parallel. Such parallel combination of several legs is then connected in series with the third semiconductor device to provide the integrated normally-off arrangement. For example, two legs (two half-bridges) may result in a full-bridge (also referred to as H bridge).

In an embodiment, the first semiconductor device and the second semiconductor device are high electron mobility transistors.

In an embodiment, the first semiconductor device and the second semiconductor device are III-nitride based semiconductor devices.

A typical HEMT (high electron mobility transistor) may comprise a substrate, which may be formed from GaN, Si, SiC, or sapphire. Disposed over the substrate may be a first III-nitride semiconductor such as GaN. A second semiconductor body formed of another III-nitride semiconductor of a different band gap such as AlGaN may be disposed over the first semiconductor body. There may be several layers of first and second semiconductor arranged over each other resulting in a stacked layered structure (or buffer).

In an embodiment, the first semiconductor device and the second semiconductor device are normally-on transistors.

In an embodiment, the third semiconductor device comprises at least one normally-off transistor.

The normally-off transistor is in particular a low-voltage field effect transistor.

In an embodiment, the third semiconductor device comprises at least two normally-off transistors that are arranged in parallel to each other.

In an embodiment, the third semiconductor device is a III-nitride based semiconductor device.

In an embodiment, the third semiconductor device is implemented in a trench in a GaN buffer.

In an embodiment, the device further comprises a fourth semiconductor device and a fifth semiconductor device, wherein the first, second, fourth and fifth semiconductor devices are coupled to form a H bridge.

Such H bridge is also referred to as full-bridge. It is noted that a total of n half-bridge legs may be arranged in parallel to each other to implement an n-leg bridge. The n half-bridge legs are connected in series with the third semiconductor device.

In an embodiment, the fourth semiconductor device and the fifth semiconductor device are high electron mobility transistors.

In an embodiment, the fourth semiconductor device and the fifth semiconductor device are III-nitride based semiconductor devices.

In an embodiment, the fourth semiconductor device and the fifth semiconductor device are normally-on transistors.

Although various exemplary embodiments of the invention have been disclosed, it will be apparent to those skilled in the art that various changes and modifications can be made which will achieve some of the advantages of the invention without departing from the spirit and scope of the invention. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods of the invention may be achieved in either all software implementations, using the appropriate processor instructions, or in hybrid implementations that utilize a combination of hardware logic and software logic to achieve the same results. Such modifications to the inventive concept are intended to be covered by the appended claims.

What is claimed is:

1. An integrated semiconductor device comprising:
a first semiconductor device;
a second semiconductor device; and
a third semiconductor device;
wherein the first semiconductor device and the second semiconductor device are integrated to form a half-bridge; and
wherein the third semiconductor device comprises a normally-off semiconductor device that is arranged in series with the half-bridge.

2. The device according to claim 1, wherein the first semiconductor device and the second semiconductor device comprise high electron mobility transistors.

3. The device according to claim 1, wherein the first semiconductor device and the second semiconductor device comprise III-nitride based semiconductor devices.

4. The device according to claim 1, wherein the first semiconductor device and the second semiconductor device comprise normally-on transistors.

5. The device according to claim 1, wherein the third semiconductor device comprises a normally-off transistor.

6. The device according to claim 1, wherein the third semiconductor device comprises a plurality of normally-off transistors arranged in parallel to each other.

7. The device according to claim 1, wherein the third semiconductor device comprise a III-nitride based semiconductor device.

8. The device according to claim 1, wherein the third semiconductor device is implemented in a trench in a GaN buffer.

9. The device according to claim 1, further comprising a fourth semiconductor device and a fifth semiconductor device, wherein the first, second, fourth and fifth semiconductor devices are coupled to form a H bridge.

10. The device according to claim 9, wherein the fourth semiconductor device and the fifth semiconductor device comprise high electron mobility transistors.

11. The device according to claim 9, wherein the fourth semiconductor device and the fifth semiconductor device comprise III-nitride based semiconductor devices.

12. The device according to claim 9, wherein the fourth semiconductor device and the fifth semiconductor device comprise normally-on transistors.

13. An integrated semiconductor device comprising:
a first normally-on high electron mobility transistor;
a second normally-on high electron mobility transistor, wherein the first high electron mobility transistor and the second high electron mobility transistor are integrated to form a half-bridge; and
a normally-off transistor arranged in series with the half-bridge.

14. The device according to claim 13, wherein the first high electron mobility transistor and the second high electron mobility transistor comprise III-nitride based semiconductor devices.

15. The device according to claim 13, further comprising a second normally-off transistor arranged in parallel with the normally-off transistor.

16. The device according to claim 13, wherein the normally-off transistor comprises a III-nitride based semiconductor device.

17. The device according to claim 13, wherein the normally-off transistor is implemented in a trench in a GaN buffer.

18. The device according to claim 13, further comprising a third normally-on high electron mobility transistor and a fourth normally-on high electron mobility transistor, wherein the first, second, third and fourth high electron mobility transistors are coupled to form an H bridge.

19. The device according to claim 18, wherein the third high electron mobility transistor and the fourth high electron mobility transistor comprise III-nitride based semiconductor devices.
